(19) United States
(12) Patent Application Publication
(10) Pub. No.: US 2026/0123117 A1
(43) Pub. Date: Apr. 30, 2026

(54) ELECTRONIC DEVICE

(71) Applicant: InnoLux Corporation, Miao-Li County (TW)

(72) Inventors: Wen-Tse Li, Miao-Li County (TW); Shih-Fu Liao, Miao-Li County (TW); I-An Yao, Miao-Li County (TW)

(73) Assignee: InnoLux Corporation, Miao-Li County (TW)

(21) Appl. No.: 19/333,409

(22) Filed: Sep. 19, 2025

(30) Foreign Application Priority Data
Oct. 24, 2024 (CN) 202411490791.0

(51) Int. Cl. H10H 20/855; H10H 29/32; H10H 29/37; H10H 29/45; H10H 29/80; H10H 29/85; H10H 29/851; H10H 29/855

(52) U.S. Cl. CPC H10H 20/855; H10H 29/32; H10H 29/37; H10H 29/45; H10H 29/842; H10H 29/8508; H10H 29/8515; H10H 29/8517; H10H 29/8552; H10H 29/882

(57) ABSTRACT

An electronic device includes a second substrate disposed relative to a first substrate, a first light-emitting unit disposed between the first substrate and the second substrate, a first microstructure on the first surface of the first light-emitting unit and the first surface away from the first substrate, and an adhesive layer disposed between the second substrate and the first surface of the first light-emitting unit. There is a first gap between the adhesive layer and the first microstructure.

### BACKGROUND OF THE DISCLOSURE

### 1. Field of the Disclosure

The present disclosure relates to an electronic device, in particular to an electronic device with a gap disposed between an adhesive layer and a light-emitting unit.

### 2. Description of the Prior Art

With the development of technology and the demand for use, a device involving a light-emitting diode (LED) has gradually become popular in daily lives. A light-emitting diode (LED) (for example, a micro-LED) in a flip chip type is often designed to have a surface microstructure on its illuminating surface to increase the light output of the LED. However, the full attachment process may affect the microstructure to result in a decrease in the brightness of the light-emitting diode. Therefore, it is necessary to provide an improved light-emitting diode structure to maintain the light output of the light-emitting diodes.

### SUMMARY OF THE DISCLOSURE

According to some embodiments of the present disclosure, an electronic device capable of maintaining the luminance output of a light-emitting diode is provided. An electronic device includes a first substrate, a second substrate, a first light-emitting unit, and an adhesive layer. The second substrate is disposed relative to a first substrate. The first light-emitting unit is disposed between the first substrate and the second substrate. The first microstructure is disposed on the first surface of the first light-emitting unit. The first surface is away from the first substrate. The adhesive layer is disposed between the second substrate and the first surface of the first light-emitting unit. There is a first gap between the adhesive layer and the first microstructure.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a schematic cross-sectional view of a first embodiment of an electronic device according to the present disclosure.

FIG. 2 illustrates a schematic variant embodiment corresponding to FIG. 1.

FIG. 3 illustrates a partial enlarged schematic view of another embodiment of the first surface of the first light-emitting unit, the second surface of the second light-emitting unit or the third surface of the third light-emitting unit corresponding to FIG. 1.

FIG. 4 illustrates a partially enlarged schematic view corresponding to an embodiment of the upper surface in FIG. 3.

FIG. 5 is a schematic cross-sectional view of an electronic device according to a second embodiment of the present disclosure.

FIG. 6 illustrates a schematic cross-sectional view of an electronic device according to a third embodiment of the present disclosure.

FIG. 7 illustrates a schematic cross-sectional view of an electronic device according to a fourth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a simplified diagram, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used to specify the presence of stated features, regions, steps, operations and/or elements and does not exclude the presence or addition of one or more other features, regions, steps, operations, elements and/or combinations thereof.

When a component or a film layer is referred to as “disposed on another component or another film layer” or “extended to another component or another film layer”, it can mean that the component or film layer is directly disposed on another component or film layer, or directly extended to another component or film layer, or there may be other components or film layers in between. In contrast, when a component is said to be “directly disposed on another component or film” or “directly extended to another component or film”, there is no component or film between the two. When an element is referred to as “connected to” another element in some embodiment of the present disclosure, it can mean that the element directly contacts another element, or indirectly contacts (such as electrically connected) another element via one or more other elements between the two elements.

The terms “about”, “substantially”, “equal”, or “same” generally mean within 20% of a given value or range, or mean within 10%, 5%, 3%, 2%, 1%, or 0.5% of a given value or range.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

The technical features in different embodiments described in the following may be replaced, recombined, or mixed with one another to constitute another embodiment without departing from the spirit of the present disclosure.

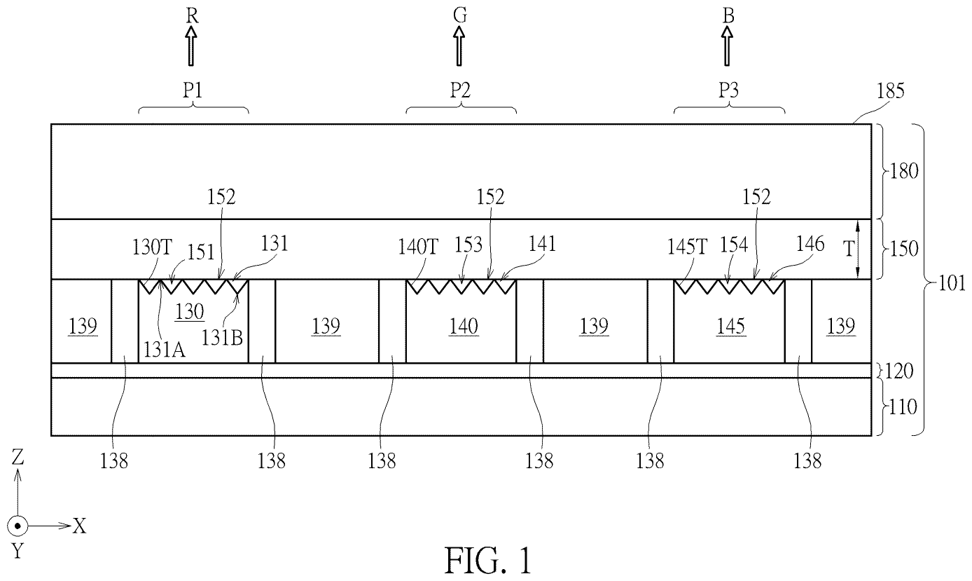

FIG. 1 is a schematic cross-sectional view of a first embodiment of an electronic device 101 according to the present disclosure. The electronic device 101 of the present disclosure, for example, includes a light-emitting diode, which may include, for example, a mini light-emitting diode (mini LED), a micro light-emitting diode (micro LED) or a quantum dot light-emitting diode (quantum dot LED, which may be, for example, QLED, QDLED), fluorescence, phosphor or other suitable materials, and the materials may be optionally combined, but the present disclosure is not limited thereto. Each embodiment of the present disclosure illustrates a plurality of light-emitting units disposed on a substrate, and the light-emitting units include micro light-emitting diodes to be taken as an example, but the present disclosure is not limited thereto.

The electronic device of the present disclosure may include, for example, a first substrate 110, a circuit layer 120, a first light-emitting unit 130, an optional second light-emitting unit 140, an optional third light-emitting unit 145, an adhesive layer 150, an optional light conversion layer 160, an optional color filter layer 170 and a second substrate 180, but the present disclosure is not limited thereto. FIG. 1 illustrates an electronic device 101 of the present disclosure including a first substrate 110, a circuit layer 120, a first light-emitting unit 130, a second light-emitting unit 140, a third light-emitting unit 145, an adhesive layer 150 and a second substrate 180. The second substrate 180 may be disposed relative to the first substrate 110, and a space for accommodating at least one light-emitting unit and the adhesive layer 150 may be formed between the second substrate 180 and the first substrate 110.

The first substrate 110 may be used to support the circuit layer 120. The first substrate 110 and the second substrate 180 may be a hard transparent material, such as glass, or any suitable material, but the present disclosure is not limited thereto. The Z direction in each figure is the stacking direction of the first substrate 110, of the circuit layer 120, of the first light-emitting unit 130, of the adhesive layer 150 and of the second substrate 180 of the electronic device, or the thickness direction of the film layer, or may also be regarded as the normal direction of the first substrate 110. The X direction and the Y direction in each figure are parallel to the surface of the first substrate 110, and the X direction is perpendicular to the Y direction. In each figure, the X direction and the Y direction are perpendicular to the Z direction.

The circuit layer 120 may be disposed on the first substrate 110. The circuit layer 120 may include a composite layer structure which includes various electronic components (not shown), conductive layers (not shown) and insulating layers (not shown) suitable for use in the electronic device, and may be electrically connected to the first light-emitting unit 130, to the second light-emitting unit 140 and to the third light-emitting unit 145. The composite layer structure may include, for example, multiple conductive layers and multiple insulating layers, to provide the needed circuit pattern and distribution by connecting the multiple conductive layers between the multiple insulating layers. The materials of the conductive layer in the circuit layer 120 may include, for example, copper, electroplated copper, other suitable conductive materials, or a combination thereof, but the present disclosure is not limited thereto. The insulating layer in the circuit layer 120 may include, for example, an organic material or an inorganic material. The organic material or the inorganic material may include, for example, a photosensitive polyimide (PSPI), an ABF film, silicon oxide (SiOx), silicon nitride (SiNx), silicon oxynitride (SiOxNy), other suitable insulating materials, or a combination thereof, but the present disclosure is not limited thereto.

The electronic components included in the circuit layer 120 may be, for example, an electronic component array, an active component, a passive component, wires, a bonding pad, a common electrode, or a transistor (not shown) electrically connected to and controlling the light-emitting units, but the present disclosure is not limited thereto. The passive component and the active component, such as a capacitor, a resistor, an inductor, a sensor, a diode, a transistor, a semiconductor component, an integrated circuit (IC), a printed circuit board (PCB), etc. In some examples, the transistor may be a thin film transistor (TFT) responsible for the on/off state of the light-emitting units. The thin film transistor is, for example, a switch element, a driving element or a transistor of other functions, but the present disclosure is not limited thereto. The thin film transistor may include a semiconductor material layer, a gate, a gate dielectric layer, a source and a drain electrically connected to the semiconductor material layer, but the present disclosure is not limited thereto. The semiconductor material layer may include amorphous silicon, polycrystalline silicon such as low temperature poly silicon (LTPS), or a metal oxide semiconductor material such as indium gallium zinc oxide (IGZO) or indium gallium oxide (IGO), other suitable materials, or a combination thereof, but the present disclosure is not limited thereto. In some examples, different transistors may include different semiconductor materials, but the present disclosure is not limited thereto. The semiconductor material layer may further include a source contact region, a drain contact region, and a channel disposed between the source contact region and the drain contact region and corresponding to a gate in a thin film transistor. The semiconductor material layer may define a channel. In a top view direction of Z (i.e., the normal direction of the surface of the first substrate 110), the semiconductor material layer and the gate at least partially overlap, and a dielectric material is arranged between the semiconductor material layer and the gate as a gate dielectric layer. The gate dielectric layer may be an insulating layer, but the present disclosure is not limited thereto, and may be optionally adjusted. The thin film transistor disclosed in the present disclosure is only an example, and the type or structure of the thin film transistor may be optionally adjusted, but the possible type or structure of the thin film transistor disclosed in the present disclosure is not limited thereto, so any other suitable thin film transistor structure may replace the above-mentioned thin film transistor. The first electrode layer (not shown) in the circuit layer 120 electrically connected to the transistor may be used to transfer the current from the transistor to the corresponding light-emitting unit. The second electrode layer (not shown) in the circuit layer 120 electrically connected to the transistor may include a common electrode for use in a plurality of light-emitting units.

The first light-emitting unit 130 is disposed between the first substrate 110 and the second substrate 180, for example, disposed on the surface of the first substrate 110. The circuit layer 120 may be disposed between the first substrate 110 and the first light-emitting unit 130. Optionally, a plurality of light-emitting units may be accommodated between the first substrate 110 and the second substrate 180. The plurality of light-emitting units may be micro light-emitting diodes, for example, but the present disclosure is not limited thereto. A plurality of light-emitting units may be used to emit blue light with a main peak (maximum peak) wavelength in the range of 420 nanometers (nm) to 460 nm, or to emit green light with a main peak wavelength in the range of 510 nm to 540 nm, or to emit red light with a main peak wavelength in the range of 610 nm to 640 nm, to obtain better optical performance, but the present disclosure is not limited thereto. One side size of the micro-LED chip may be 10 μm to 100 μm, and the area of the micro-LED chip may be 100 square μm to 5000 square μm, but the present disclosure is not limited thereto. FIG. 1 illustrates that three light-emitting units are disposed on the first substrate 110, but the present disclosure is not limited thereto

As shown in FIG. 1, the electronic device may include a plurality of pixel regions. A plurality of light-emitting units may be disposed on a surface (for example, a surface of an X direction and a Y direction) of the first substrate 110, between the first substrate 110 and the second substrate 180. On the surface of the first substrate 110, a plurality of light-emitting units may be arranged in a matrix, but the present disclosure is not limited thereto. To simplify the description, FIG. 1 shows three pixel regions P1, P2, P3, and shows three light-emitting units, but the present disclosure is not limited thereto. Specifically speaking, the first light-emitting unit 130 is disposed in the first pixel region P1, the second light-emitting unit 140 is disposed in the second pixel region P2, and the third light-emitting unit 145 is disposed in the third pixel region P3. On an illuminating surface 185 of the second substrate, different pixel regions may emit light of different colors. In some embodiments, the color of the light emitted from the pixel regions is not limited, such as red, green, or blue. For example, on the illuminating surface 185 of the second substrate 180, the first pixel region P1 may emit light of a first color, the second pixel region P2 may emit light of a second color, and the first color and the second color may be different. For explanation, specifically speaking, the first pixel region P1 may emit red light, the second pixel region P2 may emit green light, and the third pixel region P3 may emit blue light.

The plurality light-emitting units may include of light-emitting units emitting specific colors, for example, may include at least one of a red light-emitting unit, a green light-emitting unit and a blue light-emitting unit, but the present disclosure is not limited thereto. Each light-emitting unit may be used to emit monochromatic light with a particularly narrow full width at half maximum of the main peak (maximum peak), such as blue light, green light, or red light, to obtain better optical performance, but the present disclosure is not limited thereto. According to some embodiments of the present disclosure, the first light-emitting unit 130, the second light-emitting unit 140 and the third light-emitting unit 145 may be light-emitting units which emit light of the same color. According to some other embodiments of the present disclosure, the first light-emitting unit 130 emits light of a first color, the second light-emitting unit 140 emits light of a second color, and the first color and the second color are different. For example, the first light-emitting unit 130, the second light-emitting unit 140 and the third light-emitting unit 145 may be light-emitting units which emit light of different colors. According to some embodiments, in FIG. 1, the first light-emitting unit 130, the second light-emitting unit 140 and the third light-emitting unit 145 may be light-emitting units which emit light of different colors. For example, the first light-emitting unit 130 may be a light-emitting unit which emits red light, the second light-emitting unit 140 may be a light-emitting unit which emits green light, and the third light-emitting unit 145 may be a light-emitting unit which emits blue light, but the present disclosure is not limited thereto.

In some examples, each light-emitting unit may include, for example (but not limited to), a micro light-emitting diode. Each micro LED may be used to define a pixel (or sub-pixel) or considered as a pixel (or sub-pixel) and generate light of a predetermined wavelength. For example, each light-emitting unit may correspond to one of a red pixel, a green pixel, a blue pixel, or other colors or wavelengths or a combination thereof, but the present disclosure is not limited thereto.

As shown in FIG. 1, a pixel definition layer 139 (PDL) may be disposed between two adjacent light-emitting units. Each pixel defining layer 139 may be disposed on the first substrate 110. For example, the pixel defining layer 139 may be disposed between the light-emitting unit 130 and the light-emitting unit 140, or between the light-emitting unit 140 and the light-emitting unit 145. The pixel definition layer 139 may include various organic or inorganic materials, such as black or white photoresist, but the present disclosure is not limited thereto. The top surface of the pixel defining layer 139 may be not lower than the top surface of each light-emitting unit, but the present disclosure is not limited thereto. The pixel defining layer 139 may be used for light shielding to reduce the possibility of light mixing between adjacent light-emitting units to influence the image quality of the display device. The pixel definition layer 139 may also have a reflective function to improve the light utilization efficiency of the light-emitting unit, but the present disclosure is not limited thereto.

As shown in FIG. 1, the fixing glue 138 may be disposed between adjacent light-emitting units and the pixel defining layer 139 to respectively fix the positions of the light-emitting units and the pixel defining layer 139. The fixing glue 138 may, for example, directly contact the surface of the adjacent light-emitting units, the surface of the pixel defining layer 139, and the surface of the adhesive layer 150. For example, the fixing glue 138 may be disposed between the light-emitting unit 140 and the pixel defining layer 139, and may directly contact the sidewall of the light-emitting unit 140, the sidewall of the pixel defining layer 139, and the lower surface 152 of the adhesive layer 150. The cured fixing glue 138 may fix the light-emitting unit on the first substrate 110 to enhance the bonding strength between the light-emitting unit and the first substrate 110. The fixing glue 138 may include a suitable adhesive material. The height of the top surface of the fixing glue 138 may be not higher than the top surface of the adjacent light-emitting unit or the top surface of the pixel defining layer 139.

The adhesive layer 150 may be disposed between the second substrate 180 and the light-emitting unit and respectively cover the top surfaces of the light-emitting units, for example, disposed between the second substrate 180 and the first surface 130T of the first light-emitting unit 130, disposed between the second substrate 180 and the second light-emitting unit 140, and between the second substrate 180 and the third light-emitting unit 145, but the present disclosure is not limited thereto. The adhesive layer 150 may include, for example, an adhesive material and directly contact the surface of the second substrate 180, of the fixing glue 138, of the light-emitting unit, and of the pixel defining layer 139. The cured adhesive material may fix the light-emitting unit on the second substrate 180 to enhance the bonding strength between the light-emitting units and the second substrate 180.

The adhesive material in the adhesive layer 150 may include a substantially transparent optical polymer material, such as at least one of an optical clear resin (OCR) or an optical clear adhesive (OCA), to attach the second substrate 180 to the light-emitting unit without substantially affecting the light-emitting intensity of the electronic device 101. The adhesive material may be a material of high light transmittance. For example, the light transmittance of the adhesive material may be greater than or equal to 95% (light transmittance ≥95%), but the present disclosure is not limited thereto. In other words, the transmittance of the adhesive material with respect to light of a wavelength between 380 nm˜780 nm is greater than or equal to 958. Or, the transmittance of the adhesive material with respect to light of a wavelength of 550 nm is greater than or equal to 958, but the present disclosure is not limited thereto. The composition of the adhesive material may be acrylic, siloxane, silicone, or epoxy resin, but the present disclosure is not limited thereto. The composition of the optically transparent resin may be, for example, polymethyl methacrylate, and the composition of the optically transparent adhesive may be, for example, polyurethane acrylic resin, but the present disclosure is not limited thereto.

As shown in FIG. 1, the adhesive layer 150 may have a thickness T in a cross-sectional view. The thickness T is the maximum dimension of the adhesive layer 150 in the Z direction. In some embodiments, the range of the thickness T may be 0.1 μm≤T<300 μm, or between 60 μm and 0.5 μm, that is, 0.5 μm≤T≤60 μm, for example, 0.1 μm≤T≤300 μm, for example, 0.2 μm≤T≤250 μm, for example, 2 μm≤T≤150 μm, but the present disclosure is not limited thereto.

According to some embodiments of the present disclosure, the adhesive layer 150 formed by an adhesive material has a storage modulus. The storage modulus represents the deformation energy of the adhesive layer 150. In some examples, the storage modulus may be greater than or equal to 10 KPa and may be less than or equal to 2000 KPa, that is, 10 KPa≤storage modulus≤2000 KPa, for example, 100 KPa≤storage modulus≤1000 KPa, or for example, 200 KPa≤storage modulus≤500 KPa, but the present disclosure is not limited thereto. According to some other embodiments of the present disclosure, the adhesive layer 150 formed by an adhesive material has a loss modulus. The loss modulus represents the loss energy of the adhesive layer 150. In some examples, it is possible that 5 KPa≤loss modulus≤200 KPa, for example 10 KPa≤loss modulus≤100 KPa, or such as 20 KPa≤loss modulus≤80 KPa. According to some other embodiments of the present disclosure, the loss factor (tan δ) of the adhesive layer 150 is the ratio of the loss modulus to the storage modulus, that is, loss factor=loss modulus/storage modulus. The loss factor may be greater than 0 and less than 1, that is, 0<tan δ<1, such as 0.01<tan δ<0.4, or such as 0.1<tan δ<0.25. The smaller loss factor of the adhesive layer 150 is conducive for maintaining the light output of the light-emitting unit in each electronic device of the present disclosure. The loss factor of the adhesive layer 150 may be obtained by measuring the loss modulus and the storage modulus of the adhesive material of the adhesive layer 150 using an instrument. For example, DMA may be used to measure the viscosity and the damping phase (tan δ) represented by the loss modulus and the storage modulus of the adhesive layer 150.

As shown in FIG. 1, the first surface 130T (first upper surface) of the first light-emitting unit 130 may have a first microstructure 131. The first surface 130T is a surface away from the first substrate 110. Similarly, as shown in FIG. 1, the second surface 140T of the second light-emitting unit 140 may have a second microstructure 141 for example, and the third surface 145T of the third light-emitting unit 145 may have a third microstructure 146. The second surface 140T is away from the first substrate 110. In some examples, the microstructure includes a periodically arranged structure. A periodically arranged structure means that the arranged structure has a minimum arrangement unit, and the minimum arrangement units are repeatedly arranged along an arranged direction, such as the X direction or the Y direction, to form a periodically arranged structure. Or, in some examples, the microstructure includes an irregularly arranged structure. An irregularly arranged structure means that the arranged structure has no common arrangement units. For example, as shown in FIG. 1, the first surface 130T of the first light-emitting unit 130, the second surface 140T of the second light-emitting unit 140 and the third surface 145T of the third light-emitting unit 145 may each have a periodically arranged structure formed of the smallest arrangement unit which repeats along the arranged direction.

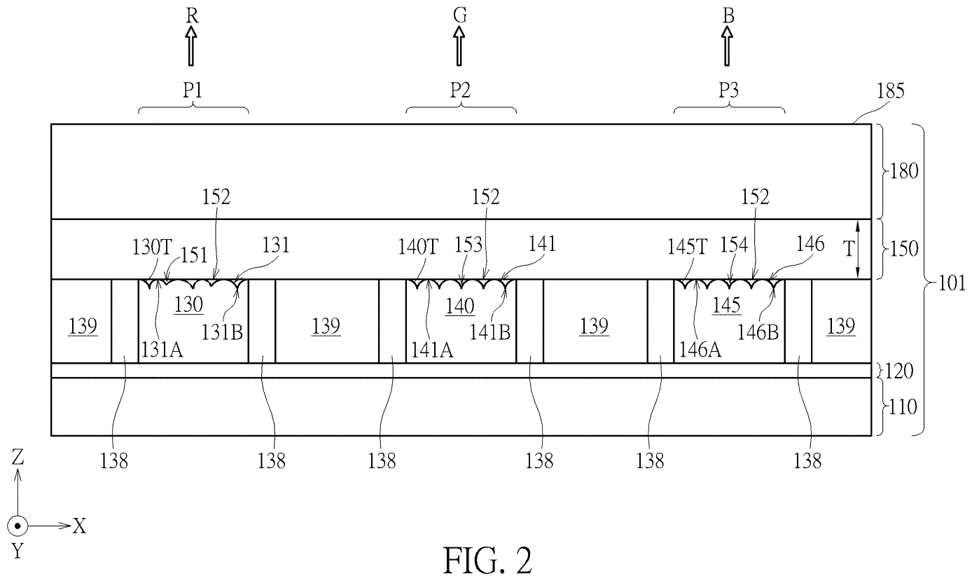

FIG. 2 illustrates a schematic variant embodiment corresponding to FIG. 1. The surface of the light-emitting unit may have a plurality of protrusion structures. In a cross-sectional view, a top of one of the plurality of protrusion structures may be arc-shaped. The regularly arranged or irregularly arranged first microstructures 131 in FIG. 1 or in FIG. 2 include a plurality of first protrusion structures 131A and a plurality of first concave structures 131B. For example, the first surface 130T of the first light-emitting unit 130 shown in FIG. 2 includes a first microstructure 131 of irregularly arranged structures, and the top of one of the plurality of first protrusion structures 131A is arc-shaped, but the present disclosure is not limited thereto. The second microstructure 141 or the third microstructure 146 may also respectively include a periodically arranged structure or an irregularly arranged structure. FIG. 1 or FIG. 2 respectively illustrates that a microstructure including a plurality of protrusion structures may increase the light output of each light-emitting unit. The position indicated by the lower surface 152 of the adhesive layer 150 shown in FIG. 1 or in FIG. 2 may be flat.

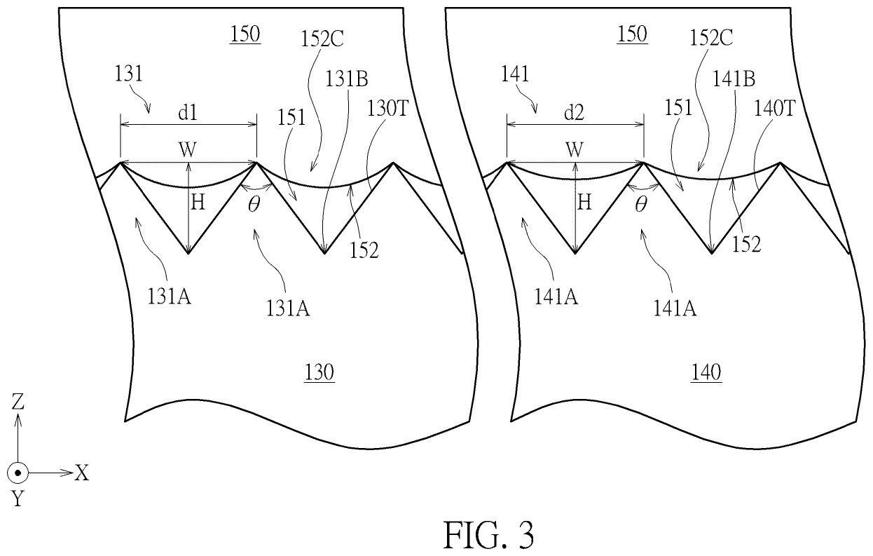

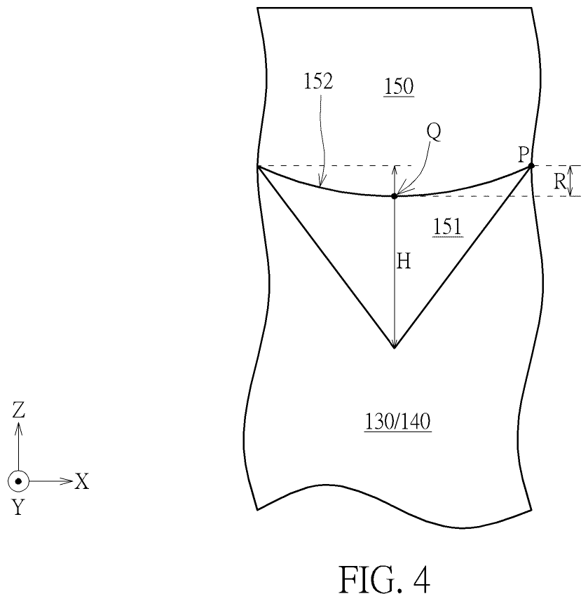

FIG. 3 illustrates a partial enlarged schematic view of another embodiment of the first surface 130T of the first light-emitting unit 130, the second surface 140T of the second light-emitting unit 140 or the third surface 145T of the third light-emitting unit 145 corresponding to FIG. 1. FIG. 4 illustrates a partially enlarged schematic view corresponding to an embodiment of the upper surface in FIG. 3. The surface of a light-emitting unit may have a plurality of protrusion structures. In a cross-sectional view, a top of one of the plurality of protrusion structures has an acute angle. The acute angle of the top portion may have an included angle θ. In some examples, the included angle θ may be greater than 0°. In other examples, the included angle θ may be less than 90°, such as 0°<θ<90°, such as 10°<θ<80°, such as 20°<θ<70°, but the present disclosure is not limited thereto. For example, the first surface 130T of the first light-emitting unit 130 shown in FIG. 3 has a periodically arranged structure formed of repeating the smallest arrangement units along the arranged direction. The smallest arrangement unit may be the first microstructure 131 including the first protrusion structure 131A and the first concave structure 131B. The top of one of the plurality of protrusion structures in the periodically arranged structure has an acute angle. The position indicated on the lower surface 152 of the adhesive layer 150 shown in FIG. 3 may not be flat.

As illustrated in FIG. 2 or in FIG. 3, the upper surface of a light-emitting unit may have a plurality of protrusion structures. In a cross-sectional view, in one direction, there is a minimum straight-line distance between two adjacent protrusion structures among the plurality of protrusion structures. This distance may be between 0.1 μm and 10 μm. For example, taking the first surface 130T of the first light-emitting unit 130 as an example, the first surface 130T of the first light-emitting unit 130 has a first microstructure 131. The first microstructure 131 has a plurality of first protrusion structures 131A. In one direction of the cross-sectional view, a distance d1 between two adjacent first protrusion structures 131A in the plurality of first protrusion structures 131A may be between 0.1 μm and 10 μm, that is, 0.1 μm≤d1≤10 μm, such as 0.2 μm≤d1≤8 μm, or such as 0.5 μm≤d1≤7 μm, but the present disclosure is not limited thereto. Or taking the second surface 140T of the second light-emitting unit 140 as an example, the second surface 140T of the second light-emitting unit 140 has a second microstructure 141. The second microstructure 141 has a plurality of second protrusion structures 141A and second concave structures 141B. In one direction of the cross-sectional view, a distance d2 between two adjacent second protrusion structures 141A in the plurality of second protrusion structures 141A may be between 0.1 μm and 10 μm, that is, 0.1 μm≤d2≤10 μm, such as 0.2 μm≤d2≤8 μm, such as 0.5 μm≤d2≤7 μm, but the present disclosure is not limited thereto. According to some embodiments of the present disclosure, the distance d1 and the distance d2 may be the same. According to some other embodiments of the present disclosure, the distance d1 and the distance d2 may be different. FIG. 1 illustrates that the third surface 145T of the third light-emitting unit 140 may have a third microstructure 146. The third microstructure 146 may include a plurality of third protrusion structures 146A and third concave structures 146B.

As shown in FIG. 3, the first microstructure 131 of the first light-emitting unit 130 has a plurality of first concave structures 131B. The adhesive layer 150 has a lower surface 152, and the lower surface 152 is away from the second substrate 180. The lower surface 152 has a concave portion 152C, the concave portion 152C is recessed toward the first substrate 110, and the concave portion 152C of the adhesive layer 150 overlaps the first concave structure 131B of the first light-emitting unit 130.

Please continue to refer to FIG. 1, to FIG. 2, or to FIG. 3. According to some embodiments, there is a first gap 151 between the adhesive layer 150 and the first microstructure 131 of the first light-emitting element 130. For example, there is a first gap 151 between the adhesive layer 150 and the first microstructure 131 of the first light-emitting unit 130, or there is a second gap 153 between the adhesive layer 150 and the second microstructure 141 of the second light-emitting unit 140, or there is a third gap 154 between the adhesive layer 150 and the third microstructure 146 of the third light-emitting unit 145. In other words, a gap may be formed between the lower surface 152 of the adhesive layer 150 and the surface of a light-emitting unit, for example, at least one of the first surface 130T, the second surface 140T, and the third surface 145T. According to some embodiments of the present disclosure, air may be included in each gap. In detail, the first gap 151 exists between the lower surface 152 of the adhesive layer 150 and the first microstructure 131 of the first light-emitting unit 130. The lower surface 152 of the adhesive layer 150 may directly contact the first protrusion structure 131A of the first microstructure 131.

According to some embodiments of the present disclosure, a gap such as the first gap 151 may have a width W and a depth H in a cross-sectional view. The width W is the maximum dimension of the gap in the X direction or in the Y direction. The depth H is the maximum dimension of the gap in the Z direction. In some embodiments, the width W may be between 0.05 μm and 3 μm, that is, 0.05 μm≤W≤3 μm, but the present disclosure is not limited thereto. The depth H may be between 0.05 μm and 3 μm, that is, 0.05 μm≤H≤3 μm, but the present disclosure is not limited thereto. For example, the width W and the depth H of the first gap 151 may be designed to have an appropriate ratio. According to some embodiments, a ratio (H/W) of the first depth/first width of the first gap 151 may be between 0.1 and 2.0. It may be between 0.1 and 2.0, that is, 0.1≤(H/W)≤2.0, or 0.4≤(H/W)≤1.0, but the present disclosure is not limited thereto. According to some embodiments of the present disclosure, the shapes or the sizes of the first gap 151 of the first light-emitting unit 130, of the second gap 153 of the second light-emitting unit 140, and of the third gap 154 of the third light-emitting unit 145 may be the same. According to other embodiments of the present disclosure, as illustrated in FIG. 2, the shapes or the sizes of the first gap 151 of the first light-emitting unit 130, of the second gap 153 of the second light-emitting unit 140, and of the third gap 154 of the third light-emitting unit 145 may be different.

According to some embodiments, a suitable adhesive layer 150 is selected so that there is a gap between the microstructure of the light-emitting unit and the adhesive layer 150. Specifically speaking, the adhesive layer 150 is disposed such that a first gap 151 exists between the first microstructure 131 of the first light-emitting unit 130 and the adhesive layer 150, and a second gap 153 exists between the second microstructure 141 of the second light-emitting unit 140 and the adhesive layer 150. In such a way, the brightness loss of the light-emitting unit caused by the adhesive layer 150 may be reduced and the light output efficiency of the light-emitting unit may be increased, thereby increasing the light output efficiency of the electronic device.

FIG. 4 illustrates a partially enlarged schematic view corresponding to an embodiment of the upper surface in FIG. 3. For example, the lowest point of the adhesive layer 150 in the region outside the first gap 151 is the reference point P, the lowest point of the adhesive layer 150 in the first gap 151 of a given light-emitting unit is the dangling point Q, and the distance between the dangling point Q and the reference point P in the Z direction is called a entry depth R. When the entry depth R is large, the adhesive layer 150 may affect the microstructure of the light-emitting unit, so that the brightness of the electronic device is reduced. There is a filling depth ratio R/H regarding the entry depth R of the adhesive layer 150 and the depth H of the first gap 151. According to some embodiments of the present disclosure, the filling depth ratio R/H may be not greater than 0.5, for example, between 0 and 0.5, that is, 0<(R/H)≤0.5, for example, 0.05<(R/H)≤0.4, but the present disclosure is not limited thereto. A smaller filling depth ratio R/H is conducive for reducing the influence of the adhesive layer 150 on the optical properties of the microstructure of the light-emitting unit, thereby maintaining the brightness of the electronic device.

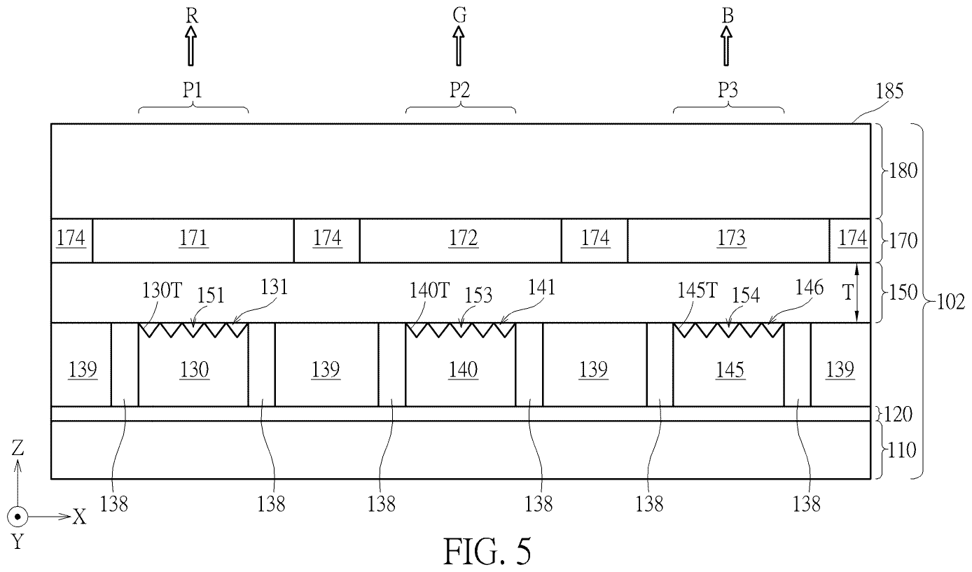

FIG. 5 is a schematic cross-sectional view of an electronic device 102 according to a second embodiment of the present disclosure. The main difference between the electronic device 102 of the second embodiment and the electronic device 101 of the first embodiment of the present disclosure resides in the electronic device 102 of the second embodiment to further include an optional color filter layer 170. The color filter layer 170 is disposed between the adhesive layer 150 and the second substrate 180, and is disposed relative to a corresponding light-emitting unit in the Z direction. The color filter layer 170 may be, for example, in direct contact with the surface of the adhesive layer 150 and with the second substrate 180.

The color filter layer 170 may include color filter elements to be respectively disposed above the illuminating sides of different light-emitting units. For example, the color filter layer 170 may include a first color filter element 171, or may further include a second color filter element 172 and a third color filter element 173. The first color filter element 171, the second color filter element 172 and the third color filter element 173 may respectively correspond to a red filter element, to a green filter element and to a blue filter element. For example, the red filter element in the color filter layer 170 is disposed between the adhesive layer 150 and the second substrate 180, and is disposed relative to the corresponding first light-emitting unit 130 in the Z direction and so on, but the present disclosure is not limited thereto. The color filter element of each color may include a suitable color material. The top surfaces of the color filter elements in the color filter layer 170 may be flush with one another to collectively form a coplanar structure.

As shown in FIG. 5, in the electronic device 102 of the second embodiment, the color filter layer 170 may include a light shielding layer 174 to be disposed between adjacent red filter elements, green filter elements and blue filter elements. The light shielding layer 174 may, for example, directly contact the surface of the adhesive layer 150 and of the second substrate 180. The light shielding layer 174 may include a light shielding material. The light shielding material may include, for example, a black material, a black photoresist, a black printing ink, a black resin, other suitable materials or a combination of the above materials, but the present disclosure is not limited thereto. The light shielding layer 174 may be a black matrix layer. The light shielding layer 174 may be disposed between two adjacent filter elements to define the positions of the red filter element, of the green filter element and of the blue filter element, and also helpful in reducing the crosstalk of light from adjacent filter elements. In the present disclosure, the output light leaving the color filter layer 170 may be regarded as the final visible light of the electronic device 102 to be perceived by a user (by an observer). The light shielding layer 174 may overlap the pixel defining layer 139.

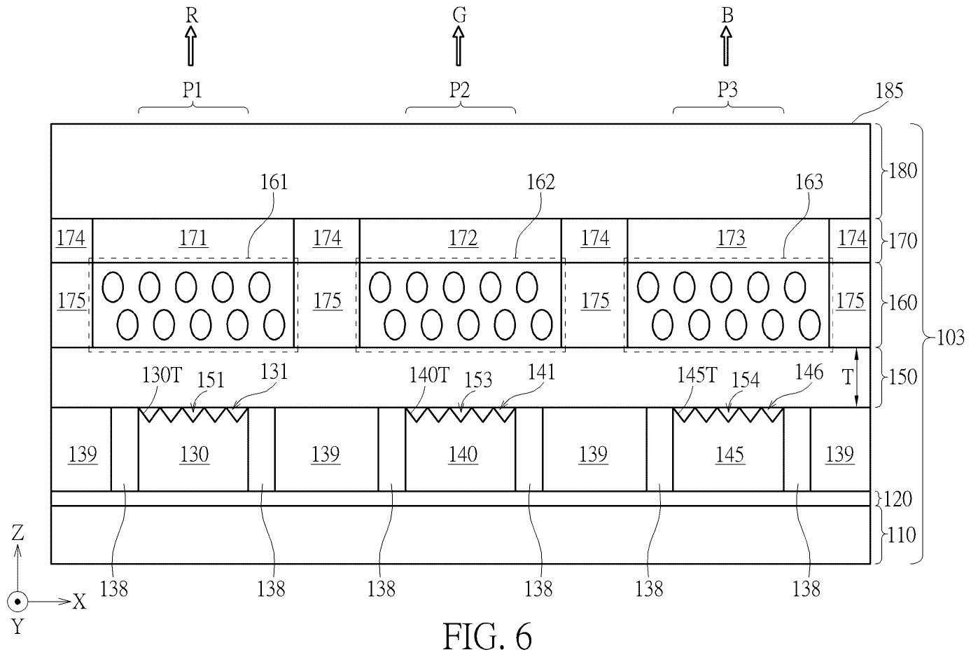

FIG. 6 illustrates a schematic cross-sectional view of an electronic device 103 according to a third embodiment of the present disclosure. The main difference between the electronic device 103 of the third embodiment and the electronic device 101 of the first embodiment of the present disclosure resides in the electronic device 103 of the third embodiment to further include an optional color filter layer 170 and an optional light conversion layer 160, and the first light-emitting unit 130, the second light-emitting unit 140 and the third light-emitting unit 145 are selected from a group consisting of a light-emitting unit emitting green light and a light-emitting unit emitting blue light. FIG. 6 illustrates that the first light-emitting unit 130 may be a light-emitting unit emitting blue light, the second light-emitting unit 140 may be a light-emitting unit emitting green light, and the third light-emitting unit 145 may be a light-emitting unit emitting blue light, but the present disclosure is not limited thereto. Replacing the first light-emitting unit 130 emitting red light with a light-emitting unit emitting blue light may help increase the light-emitting efficiency of the first light-emitting unit 130.

As shown in FIG. 6, the light conversion layer 160 may include a first light conversion element 161, an optional second light conversion element 162, or an optional third light conversion element 163. The light conversion layer 160 may be disposed between the adhesive layer 150 and the color filter layer 170 and in a normal direction of the first substrate 110, such as in the Z direction, to overlap a corresponding light-emitting unit to adjust the output light of the electronic device 103. The light conversion layer 160 may be correspondingly disposed above the illuminating side of the light-emitting unit. The color filter layer 170 in FIG. 6 is used to block, absorb or filter the light not converted by the light conversion layer 160, thereby enhancing the purity of the monochromatic light output from the light-emitting unit, so as to improve the optical performance of the electronic device 103 and enhance the color quality of the output light. Each light-emitting unit and the corresponding filter element, the light conversion layer 160 and a portion of the adhesive layer 150 may form a pixel P1. For example, the first light-emitting unit 130 and the corresponding first color filter element 171, the first light conversion element 161 and a portion of the adhesive layer 150 (overlapping the light-emitting unit 130) may collectively form a pixel P1.

The light conversion layer 160 may be a wavelength conversion element to adjust the wavelength of the output light of the electronic device 103, but the present disclosure is not limited thereto. For example, the wavelength conversion element may output blue light, cyan light, green light, yellow light, red light, or a combination thereof, but the present disclosure is not limited thereto. The wavelength conversion element includes quantum dot particles (QD particles) which convert blue light into red light or into green light, a phosphorescent material, a fluorescent material, a pigment, a dye, scattering particles, a filter layer, other suitable materials or a combination thereof, but the present disclosure is not limited thereto. The quantum dots may be made of a semiconductor nanocrystal structure. When the quantum dots are excited by the input light, the input light is converted by the quantum dots into emitted light of other colors. The color of the emitted light may be tuned by changing the material, the shape or the size of the quantum dots. In some embodiments, the quantum dots may include spherical particles, rod-shaped particles, or particles having any other suitable shape, as long as the quantum dots may emit light having a suitable color.

The optional second light conversion element 162 or the optional third light conversion element 163 may not include the quantum dot particles. For example, the second light-emitting unit 140 is a green light-emitting unit with a green filter element disposed thereon and the third light-emitting unit 145 is a blue light-emitting unit with a blue filter element disposed thereon, the second light conversion element 162 and the third light conversion element 163 may respectively not include quantum dot particles but be replaced by a scattering layer filled with scattering particles. In other words, not every light-emitting unit has a wavelength conversion element disposed thereon.

The first light conversion element 161 is disposed between the adhesive layer 150 and the color filter layer 170, and is disposed relative to the first light-emitting unit 130. The second light conversion element 162 or the third light conversion element 163 may be similarly arranged. According to some embodiments, in FIG. 6, the first light-emitting unit 130 and the third light-emitting unit 145 are blue. The first light conversion element 161 may include the quantum dot particles, the second light conversion element 162 and the third light conversion element 163 may include scattering layers. The first color filter element 171 is red, the second color filter element 172 is green, and the third color filter element 173 is blue. The first light conversion element 161 may convert the blue light emitted by the first light-emitting unit 130 into red light. Accordingly, on the illuminating surface 185 of the second substrate 180, the first pixel region P1 emits red light, the second pixel region P2 emits green light and the third pixel region P3 emits blue light.

The light conversion layer 160 may further include a barrier layer. The barrier layer includes barrier elements disposed between adjacent light conversion layers, such as a barrier element 175 disposed between adjacent first light conversion elements 161 and second light conversion elements 162, and a barrier element 175 disposed between adjacent second light conversion elements 162 and third light conversion elements 163, but the present disclosure is not limited thereto. The barrier layer may serve as a bank, but the present disclosure is not limited thereto. The barrier layer may be used to define the position of the light conversion layer 160. The light shielding layer 174 may, for example, directly contact the surface of the color filter layer 170, of the barrier layer and of the second substrate 180. The barrier layer may, for example, directly contact the surfaces of the adhesive layer 150, of the color filter layer 170, of the light shielding layer 174, and of the light conversion layer 160. The second substrate 180 may, for example, directly contact the surfaces of the color filter layer 170 and of the light shielding layer 174.

In one embodiment, the first light conversion element 161 and the second light conversion element 162 have different light emission colors. For example, when the first light-emitting unit 130 is a blue light-emitting unit, the first light conversion element 161 corresponding to the blue light-emitting unit may convert the blue light into red light, but the present disclosure is not limited thereto. When the second light-emitting unit 140 is a blue light-emitting unit, the second light conversion element 162 corresponding to the blue light-emitting unit may convert the blue light into green light, but the present disclosure is not limited thereto. Therefore, the first light-emitting unit 130 and the second light-emitting unit 140 emit the same blue light, and the first light conversion element 161 and the second light conversion element 162 emit different red and green light colors.

In another embodiment, the top surfaces of the first light conversion element 161, of the second light conversion element 162 and of the third light conversion element 163 may be flush with one another to form a coplanar structure. The coplanar structure is conducive for reducing the optical differences among the first light-emitting unit 130, the second light-emitting unit 140 and the third light-emitting unit 145. The arrangement of the first light-emitting unit 130 and the third light-emitting unit 145 in the electronic device 103 emitting light of the same color is conducive for further simplifying the structure of the electronic device 103, reducing the manufacturing complexity of the electronic device 103, and/or maintaining the optical performance of the electronic device 103.

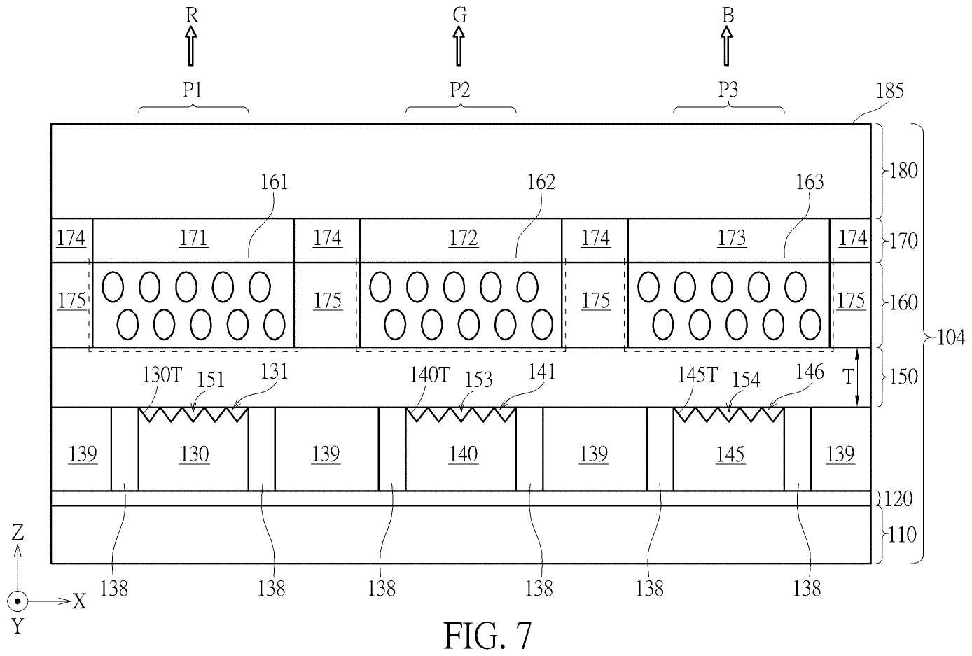

FIG. 7 illustrates a schematic cross-sectional view of an electronic device 104 according to a fourth embodiment of the present disclosure. The main difference between the electronic device 104 of the fourth embodiment and the electronic device 103 of the third embodiment of the present disclosure resides in the different configurations of the light conversion layer and of the light-emitting units in the electronic device 104 of the fourth embodiment. The electronic device 104 of the fourth embodiment shown in FIG. 7 includes light conversion elements with different output light colors and light-emitting units with the same emission light color. For example, the electronic device 104 may further include a second light conversion element 162. The second light conversion element 162 is disposed between the adhesive layer 150 and the color filter layer 170, and is disposed relative to the second light-emitting unit 140. In one embodiment, the first light-emitting unit 130 emits light of a first color and the second light-emitting unit 140 emits light of a second color. The first color and the second color may be the same, for example, the first color and the second color may be blue. In another embodiment, the first light conversion element 161 has a first output light color, the second light conversion element 162 has a second output light color, and the first output light color is different from the second output light color. For example, the first output light color is red, and the second output light color is green, but the present disclosure is not limited thereto.

The electronic device 104 may further include a third light conversion element 163. When the third color is blue and the third output light color is blue, the third light conversion element 163 may not include the quantum dot particles, and may be replaced with a scattering layer filled with scattering particles. The arrangement of the first light-emitting unit 130, of the second light-emitting unit 140 and of the third light-emitting unit 145 in the electronic device 104 to emit light of the same color is conducive for further simplifying the structure of the electronic device 104, reducing the manufacturing complexity of the electronic device 104, and/or maintaining the optical performance of the electronic device 104. According to some embodiments, in FIG. 7, the first light-emitting unit 130, the second light-emitting unit 140 and the third light-emitting unit 145 are blue. The first light conversion element 161 and the second light conversion element 162 may include the quantum dot particles, and the third light conversion element 163 may include a scattering layer. The first color filter element 171 is red, the second color filter element 172 is green, and the third color filter element 173 is blue. The first light conversion element 161 may convert the blue light emitted by the first light-emitting unit 130 into red light, and the second light conversion element 162 may convert the blue light emitted by the second light-emitting unit 140 into green light. Accordingly, on the illuminating surface 185 of the second substrate 180, the first pixel region P1 emits red light, the second pixel region P2 emits green light, and the third pixel region P3 emits blue light.

The following table lists the light output of the electronic devices of the present disclosure before and after adhesion by using three types of adhesive layers. The three adhesive layers have different loss factors (tan δ). It is observed from the data in the table that the selection of an appropriate adhesive layer is conducive for maintaining the light output of the electronic device.

| | | Brightness | |
|---|---|---|---|
| Adhesive Layer | Loss Factor | Before Adhered | After Adhered |
| Example 1 | 0.15 | 100% | 95% |
| Example 2 | 0.12 | 100% | 96% |
| Example 3 | 0.45 | 100% | 54% |

In some embodiments, a suitable adhesive layer is selected so that there is a gap between the microstructure of the illuminating surface of the light-emitting unit and the adhesive layer. In such a way, the brightness loss which may be caused by the adhesive layer may be reduced, so that the light output efficiency of the light-emitting unit may be improved.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device comprising:
a first substrate;
a second substrate disposed relative to a first substrate;
a first light-emitting unit disposed between the first substrate and the second substrate, a first microstructure on a first surface of the first light-emitting unit and the first surface away from the first substrate; and
an adhesive layer disposed between the second substrate and the first surface of the first light-emitting unit, wherein there is a first gap between the adhesive layer and the first microstructure.

2. The electronic device of claim 1, wherein the first microstructure of the first light-emitting unit has a plurality of first protrusion structures, and in a cross-sectional view, in a first direction, a first distance d1 between two adjacent the first protrusion structures in the plurality of first protrusion structures is between 0.1 μm and 10 μm.

3. The electronic device of claim 1, further comprising:
a second light-emitting unit disposed between the first substrate and the second substrate, the first light-emitting unit adjacent to the second light-emitting unit in the first direction, wherein the electronic device comprises a first pixel region and a second pixel region, the first light-emitting unit is disposed in the first pixel region, the second light-emitting unit is disposed in the second pixel region, the first pixel region emits light of a first color and the second pixel region emits light of a second color from an illuminating surface of the second substrate, and the first color and the second color are different.

4. The electronic device of claim 1, wherein a second surface of the second light-emitting unit has a second microstructure, the second surface is away from the first substrate, wherein a second gap is disposed between the adhesive layer and the second microstructure, and a size of the first gap is different from a size of the second gap.

5. The electronic device of claim 4, wherein the second microstructure of the second light-emitting unit has a plurality of second protrusion structures, and in the cross-sectional view, in the first direction, a second distance d2 between two adjacent the second protrusion structures in the plurality of second protrusion structures is between 0.1 μm and 10 μm, and the first distance and the second distance are different.

6. The electronic device of claim 1, wherein the first microstructure of the first light-emitting unit has a plurality of first protrusion structures, and in a cross-sectional view, a top of at least one of the plurality of first protrusion structures is arc-shaped.

7. The electronic device of claim 1, wherein the first microstructure of the first light-emitting unit has a plurality of first protrusion structures, and in a cross-sectional view, a top of at least one of the plurality of first protrusion structures has an acute angle.

8. The electronic device of claim 1, wherein a loss factor (tan δ) of the adhesive layer is greater than 0 and less than 1.

9. The electronic device of claim 1, wherein a storage modulus of the adhesive layer is greater than or equal to 10 KPa and less than or equal to 2000 KPa.

10. The electronic device of claim 1, wherein in a cross-sectional view, the first gap has a first depth and a first width, and a ratio of the first depth/first width is between 0.1 and 2.0.

11. The electronic device of claim 1, wherein first microstructure of the first light-emitting unit has a plurality of first concave structures, the adhesive layer has a lower surface away from the second substrate, the lower surface has a concave portion, the concave portion is recessed toward the first substrate, and the concave portion of the adhesive layer overlaps the first concave structures of the first light-emitting unit.

12. The electronic device of claim 1, further comprising:
a first color filter element disposed between the adhesive layer and the second substrate to correspond to the first light-emitting unit.

13. The electronic device of claim 12, further comprising:
a first light conversion element disposed between the adhesive layer and the first color filter element to correspond to the first light-emitting unit.

14. The electronic device of claim 1, wherein the first microstructure of the first light-emitting unit has a plurality of first concave structures.

15. The electronic device of claim 1, wherein the first microstructure comprises a periodically arranged structure.

16. The electronic device of claim 1, wherein the first microstructure comprises an irregularly arranged structure.

17. The electronic device of claim 3, further comprising:
a pixel definition layer disposed between the first light-emitting unit and the second light-emitting unit.

18. The electronic device of claim 17, further comprising:
a fixing glue disposed between the first light-emitting unit and the pixel defining layer to fix the first light-emitting unit and the pixel defining layer.

19. The electronic device of claim 12, wherein the first color filter element comprises a light shielding layer.

20. The electronic device of claim 13, wherein the first light conversion element comprises a scattering layer.
